(19) United States
(12) Patent Application Publication
(10) Pub. No.: US 2026/0344316 A1
(43) Pub. Date: Oct. 29, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Takayuki YAMAMOTO, Toyama (JP); Kaigo TAHARA, Toyama (JP); Hideki HORITA, Toyama (JP); Ryuji YAMAMOTO, Tokyo (JP)

(73) Assignee: KOKUSAI ELECTRIC CORPORATION, Tokyo (JP)

(21) Appl. No.: 19/454,966

(22) Filed: Jan. 21, 2026

(30) Foreign Application Priority Data
Jan. 23, 2025 (JP) 2025-009607

(51) Int. Cl. H10P 50/28; H10P 72/00; H10P 95/70

(52) U.S. Cl. CPC H10P 50/283; H10P 95/70; H10P 72/0421

(57) ABSTRACT

A technique includes (a) supplying a substance X to a substrate disposed in a second process chamber, which is in fluid communication with a first process chamber via a loading/unloading port, so that the substance X is adsorbed on the substrate; (b) transferring the substrate on which the substance X is adsorbed from the second process chamber into the first process chamber; and (c) supplying an etching agent to the substrate in the first process chamber and so that the etching agent reacts with the substance X to etch a surface of the substrate.

### CROSS-REFERENCE TO RELATED APPLICATION

This application is based upon and claims the benefit of priority from Japanese Patent Application No. 2025-009607, filed on Jan. 23, 2025, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as one of processes of manufacturing a semiconductor device, a process of etching a surface of a substrate may be performed.

### SUMMARY

Some embodiments of the present disclosure provide a technique capable of efficiently etching a surface of a substrate.

According to embodiments of the present disclosure, there is provided a technique that includes: (a) supplying a substance X to a substrate disposed in a second process chamber, which is in fluid communication with a first process chamber via a loading/unloading port, so that the substance X is adsorbed on the substrate; (b) transferring the substrate on which the substance X is adsorbed from the second process chamber into the first process chamber; and (c) supplying an etching agent to the substrate in the first process chamber so that the etching agent reacts with the substance X to etch a surface of the substrate.

### BRIEF DESCRIPTION OF DRAWINGS

The accompanying drawings, which are incorporated in and constitute a part of the specification, illustrate embodiments of the present disclosure.

FIG. 1 is a schematic diagram of a vertical process furnace of a processing apparatus suitably used in embodiments of the present disclosure, showing a portion of the process furnace in a vertical cross-sectional view.

FIG. 2 is a schematic diagram of the vertical process furnace of the processing apparatus suitably used in embodiments of the present disclosure, showing a portion of the process furnace in a cross-sectional view taken along line A-A in FIG. 1.

FIG. 3 is a partial cross-sectional schematic diagram showing a configuration of surroundings of the process furnace of the processing apparatus suitably used in embodiments of the present disclosure.

FIG. 4 is a schematic diagram of a controller of the processing apparatus suitably used in embodiments of the present disclosure, showing a control system of the controller in a block diagram.

FIG. 5A is a partial cross-sectional schematic diagram of the processing apparatus before step A is performed. FIG. 5B is a partial cross-sectional schematic diagram of the processing apparatus after step A is performed to adsorb a substance X to a wafer disposed in a load lock chamber. FIG. 5C is a partial cross-sectional schematic diagram of the processing apparatus after step B is performed to transfer the wafer on which the substance X is adsorbed from the load lock chamber into a process chamber. FIG. 5D is a partial cross-sectional schematic diagram of the processing apparatus showing a state in which step C is performed to supply an etching agent to the wafer in the process chamber and steps E, F and G are performed to reduce a concentration of the substance X in the load lock chamber. FIG. 5E is a partial cross-sectional schematic diagram of the processing apparatus showing a state in which step H is performed to supply a processing agent to the wafer, whose surface is etched, in the process chamber and steps E, F and G are performed to reduce the concentration of substance X in the load lock chamber. FIG. 5F is a partial cross-sectional schematic diagram of the processing apparatus after step D is performed to transfer the processed wafer from the process chamber into the load lock chamber.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

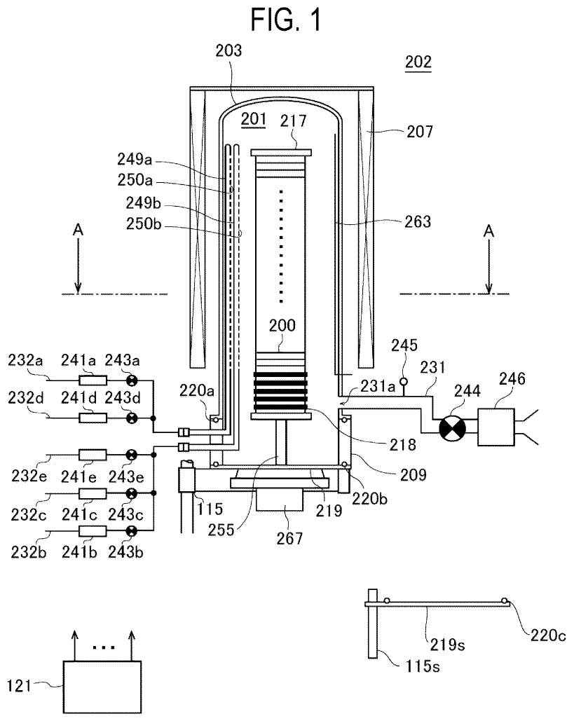

Embodiments of the present disclosure are described below primarily with reference to FIGS. 1 to 4 and FIGS. 5A to 5F. Drawings used in the following description are schematic, and dimensional relationships, proportions, and the like of elements shown in the drawings may not match actual ones. Further, the dimensional relationships, proportions, and the like of elements among multiple figures may not match one another.

### (1) Configuration of Processing Apparatus

As shown in FIG. 1, a process furnace 202 of a substrate processing apparatus (also referred to as a processing apparatus) includes a heater 207 as a temperature regulator (heating part). The heater 207 is cylindrical and is installed vertically by being supported by a holding plate. The heater 207 also functions as an activator (exciter) that thermally activates (excites) a gas.

A reaction tube 203 is disposed concentrically with the heater 207 inside the heater 207. The reaction tube 203 is formed in a cylindrical shape with a closed upper end and an open lower end. A manifold 209 is disposed concentrically with the reaction tube 203 below the reaction tube 203. An O-ring 220a serving as a seal is formed between the manifold 209 and the reaction tube 203. A process container (reaction container) mainly includes the reaction tube 203 and the manifold 209. A process chamber 201 serving as a first process chamber is formed in a cylindrical hollow portion of the process container. The process chamber 201 is configured to be capable of accommodating wafers 200 serving as substrates. The wafers 200 are processed in the process chamber 201.

Nozzles 249a and 249b serving as first and second suppliers are installed in the process chamber 201 so as to penetrate a sidewall of the manifold 209. Gas supply pipes 232a and 232b are connected to the nozzles 249a and 249b, respectively.

In the gas supply pipes 232a and 232b, mass flow controllers (MFCs) 241a and 241b, which are flow rate controllers (flow rate control parts), and valves 243a and 243b, which are on-off valves, are respectively installed in order from an upstream side of a gas flow. A gas supply pipe 232d is connected to the gas supply pipe 232a on a downstream side of the valve 243a. Gas supply pipes 232c and 232e are connected to the gas supply pipe 232b on a downstream side of the valve 243b. In the gas supply pipes 232c to 232e, MFCs 241c to 241e and valves 243c to 243e are respectively installed in order from an upstream side of a gas flow.

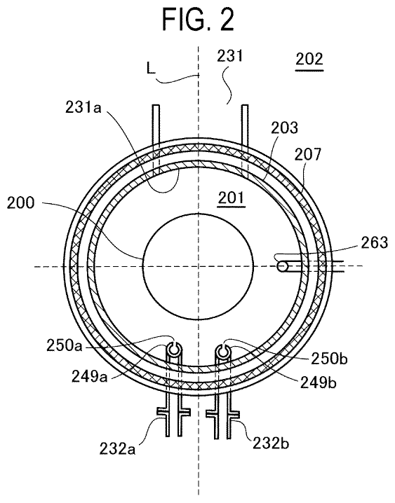

As shown in FIG. 2, the nozzles 249a and 249b are respectively installed in a space, formed in an annular shape in a plane-view, between an inner wall of the reaction tube 203 and the wafers 200 so as to extend upward in an arrangement direction of the wafers 200 along the inner wall of the reaction tube 203 from a lower portion to an upper portion of the inner wall of the reaction tube 203. Gas supply holes 250a and 250b for supplying gases are respectively formed on side surfaces of the nozzles 249a and 249b. Each of the gas supply holes 250a and 250b is capable of supplying gases toward the wafers 200. The gas supply holes 250a and 250b are formed from a lower portion to an upper portion of the reaction tube 203.

A fluorine (F)-containing substance serving as an etching agent is supplied from the gas supply pipe 232a into the process chamber 201 via the MFC 241a, the valve 243a, and the nozzle 249a.

A precursor serving as a processing agent is supplied from the gas supply pipe 232b into the process chamber 201 through the MFC 241b, the valve 243b, and the nozzle 249b. The precursor is used as one of film-forming agents.

A reducing agent serving as a processing agent is supplied from the gas supply pipe 232c into the process chamber 201 via the MFC 241c, the valve 243c, and the nozzle 249b.

An inert gas is supplied from the gas supply pipes 232d and 232e into the process chamber 201 via the MFCs 241d and 241e, the valves 243d and 243e, the gas supply pipes 232a and 232b, and the nozzles 249a and 249b, respectively. The inert gas acts as a purge gas, a carrier gas, a dilution gas, or the like.

A F-containing substance supply system serving as an etching agent supply system mainly includes the gas supply pipe 232a, the MFC 241a, and the valve 243a. A precursor supply system serving as a first processing agent supply system mainly includes the gas supply pipe 232b, the MFC 241b, and the valve 243b. A reducing agent supply system serving as a second processing agent supply system mainly includes the gas supply pipe 232c, the MFC 241c, and the valve 243c. A first inert gas supply system mainly includes the gas supply pipes 232d and 232e, the MFCs 241d and 241e, and the valves 243d and 243e. The precursor supply system is also referred to as a film-forming agent supply system.

An exhaust port 231a for exhausting an internal atmosphere of the process chamber 201 is installed below a sidewall of the reaction tube 203. An exhaust pipe 231 is connected to the exhaust port 231a. A vacuum pump 246 serving as a vacuum exhauster is connected to the exhaust pipe 231 via a pressure sensor 245 serving as a pressure detector (pressure detection part) for detecting an internal pressure of the process chamber 201 and an APC (Auto Pressure Controller) valve 244 serving as a pressure regulator (pressure regulating part). The APC valve 244 is configured to perform or stop vacuum-exhaust in the process chamber 201 by opening or closing the valve while the vacuum pump 246 is operating, and is configured to regulate the internal pressure of the process chamber 201 by adjusting a valve opening degree based on pressure information detected by the pressure sensor 245 while the vacuum pump 246 is operating. A first exhaust system mainly includes the exhaust pipe 231, the APC valve 244, and the pressure sensor 245. The vacuum pump 246 may be included in the first exhaust system.

A seal cap 219 is installed below the manifold 209 as a furnace opening lid capable of airtightly closing an opening at a lower end of the manifold 209, i.e., a loading/unloading port 204 for the wafers 200. An O-ring 220b, which serves as a seal that abuts against the lower end of the manifold 209, is formed on an upper surface of the seal cap 219. A rotator 267 is provided below the seal cap 219 to rotate the boat 217, which is described later. A rotary shaft 255 of the rotator 267 passes through the seal cap 219 and is connected to the boat 217. The rotator 267 is configured to rotate the wafers 200 by rotating the boat 217. The seal cap 219 is configured to be vertically raised or lowered by a boat elevator 115, which is a lift installed outside the reaction tube 203. The boat elevator 115 is configured as a transferrer (transfer mechanism) that transfers the wafers 200 into and out of the process chamber 201, i.e., between the process chamber 201, which serves as a first process chamber, and a load lock chamber 501, which serves as a second process chamber and is described later, by raising or lowering the seal cap 219.

A shutter 219s is installed below the manifold 209 as a furnace opening lid capable of airtightly closing the opening at the lower end of the manifold 209, i.e., the loading/unloading port 204 for the wafers 200, in a state where the seal cap 219 is lowered and the boat 217 is unloaded from the process chamber 201. The shutter 219s is formed in a disc shape. An O-ring 220c is formed on an upper surface of the shutter 219s as a seal that abuts against the lower end of the manifold 209. The opening/closing operation (raising/lowering operation, rotating operation, and the like) of the shutter 219s is controlled by a shutter opening/closing mechanism 115s.

The boat 217 serving as a substrate support is configured to support a plurality of wafers 200, for example, 25 to 200 wafers 200, in such a state that the wafers 200 are arranged in a horizontal posture and in multiple stages in a vertical direction with centers of the wafers 200 aligned with one another, i.e., to arrange the wafers 200 at intervals. The boat 217 is made of a heat-resistant material such as quartz (SiO₂) or SiC. Heat insulating plates 218 are supported in multiple stages at a lower portion of the boat 217.

A temperature sensor 263 serving as a temperature detector is installed inside the reaction tube 203. By regulating a state of supplying electric power to the heater 207 based on temperature information detected by the temperature sensor 263, an internal temperature of the process chamber 201 achieves a desired temperature distribution.

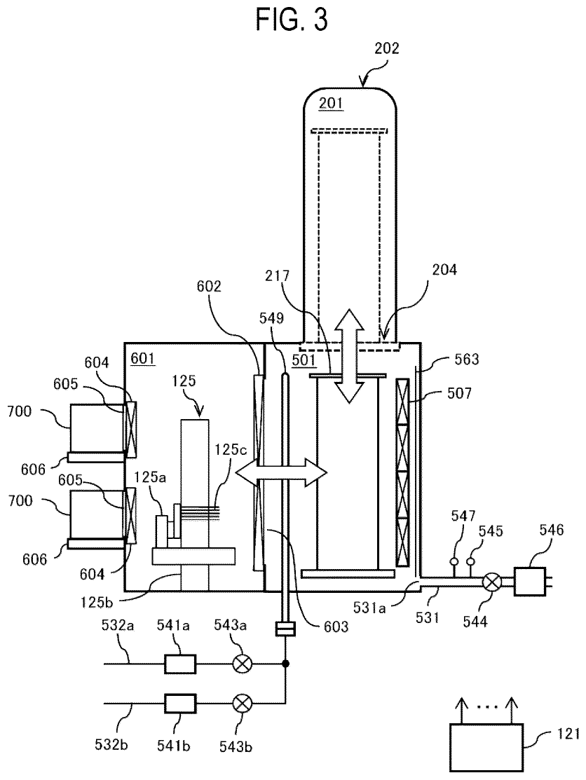

Next, a configuration of the above-mentioned process furnace 202 and the surroundings are described with reference to FIG. 3.

As shown in FIG. 3, the load lock chamber 501 serving as the second process chamber is installed below the process furnace 202. Further, a delivery chamber 601 serving as a third process chamber is installed adjacent to the load lock chamber 501. The process chamber 201 of the process furnace 202 and the load lock chamber 501 are configured to be capable of being in fluid communication with each other via a furnace opening, i.e., the loading/unloading port 204 of the process furnace 202. The load lock chamber 501 and the delivery chamber 601 are also configured to be capable of being in fluid communication with each other via a loading/unloading port 603 that is opened or closed by a gate valve 602. A wafer deliverer (delivery robot) 125 is installed in the delivery chamber 601 and is configured to be capable of removing processing target wafers 200 accommodated in a transfer container 700 and deliver the wafers 200 to the boat 217 via the loading/unloading port 603. Through a coordinated operation of a wafer delivery mechanism 125a and a wafer delivery mechanism elevator 125b, the wafer deliverer 125 is configured to charge or discharge wafers 200 into or from the boat 217 by using tweezers 125c. In addition, a loading/unloading port 605 opened or closed by an opener 604 is installed on another side of the delivery chamber 601. The loading/unloading port 605 is installed adjacent to a mounting table 606 on which the transfer container 700 is placed, and the wafers 200 accommodated in the transfer container 700 placed on the mounting table 606 are loaded or unloaded to or from the delivery chamber 601 via the loading/unloading port 605.

As described later, in the embodiments, a predetermined preparatory process (a process of adsorbing a substance X) is performed on the processing target wafer 200 in the load lock chamber 501, serving as the second process chamber sealed by the gate valve 602. Thereafter, the wafer 200 on which this preparatory process is performed is transferred into the process chamber 201 serving as the first process chamber, and a predetermined process such as an etching process, a film formation process, or the like is performed. In order to perform this preparatory process, the load lock chamber 501 according to the embodiments is installed with various pieces of equipment as described below.

First, the load lock chamber 501 is installed with a nozzle 549 as an introduction port for the substance X. A gas supply pipe 532a is connected to the nozzle 549. A MFC 541a and a valve 543a are installed in the gas supply pipe 532a in this order from an upstream side of a gas flow. A gas supply pipe 532b is connected to the gas supply pipe 532a on a downstream side of the valve 543a. A MFC 541b and a valve 543b are installed in the gas supply pipe 532b in this order from an upstream side of a gas flow. A gas containing the substance X is supplied from the gas supply pipe 532a into the process chamber 201 via the MFC 541a, the valve 543a, and the nozzle 549. An inert gas is supplied from the gas supply pipe 532b into the process chamber 201 via the MFC 541b, the valve 543b, and the nozzle 549. A substance X supply system mainly includes the gas supply pipe 532a, the MFC 541a, and the valve 543a. A second inert gas supply system mainly includes the gas supply pipe 532b, the MFC 541b, and the valve 543b. The second inert gas supply system is also referred to as a second purge gas supply system or a second dilution gas supply system.

The load lock chamber 501 is also installed with an exhaust port 531a, which is connected to an exhaust pipe 531. A vacuum pump 546 is connected to the exhaust pipe 531 via a concentration sensor 547 that measures a concentration of the substance X in the load lock chamber 501, a pressure sensor 545 that detects an internal pressure of the load lock chamber 501, and an APC valve 544. A second exhaust system mainly includes the exhaust pipe 531, the APC valve 544, the concentration sensor 547, and the pressure sensor 545.

The load lock chamber 501 is also installed with a heater 507 as a temperature regulator. A temperature sensor 563 is installed inside the load lock chamber 501. By regulating a state of supplying electric power to the heater 507 based on temperature information detected by the temperature sensor 563, an internal temperature of the load lock chamber 501 achieves a desired temperature distribution.

Next, a controller for controlling the above-mentioned processing apparatus is described.

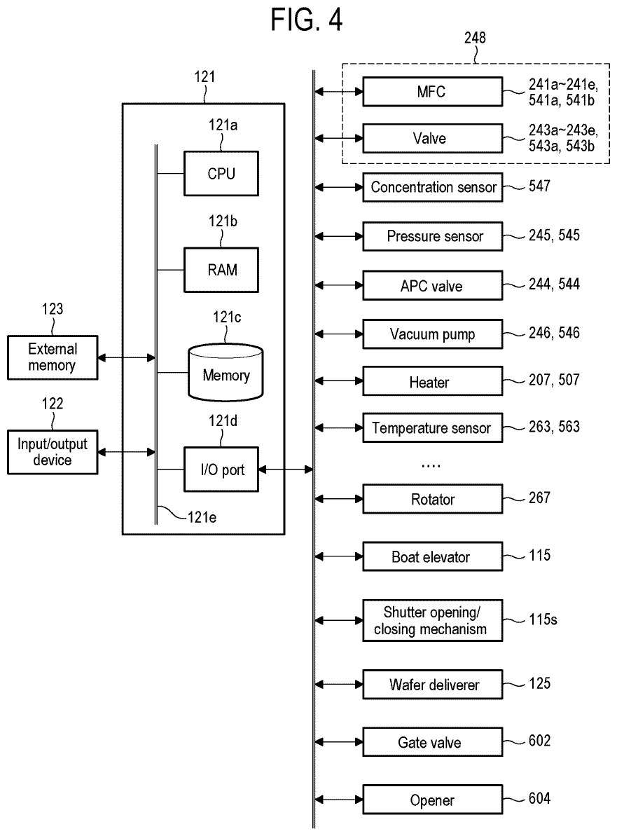

As shown in FIG. 4, a controller 121, which is a control part (control means), is configured as a computer that includes a CPU (Central Processing Unit) 121a, a RAM (Random Access Memory) 121b, a memory 121c, and an I/O port 121d. The RAM 121b, the memory 121c, and the I/O port 121d are configured to be capable of exchanging data with the CPU 121a via an internal bus 121e. An input/output device 122 formed of, for example, a touch panel or the like, is connected to the controller 121. An external memory 123 may also be connected to the controller 121. The processing apparatus may be configured to include one controller or a plurality of controllers. That is, control for performing a processing sequence described below may be performed using one controller or a plurality of controllers. Further, the plurality of controllers may be configured as a control system in which the plurality of controllers are connected to each other via a wired or wireless communication network, and the control for performing the processing sequence described below may be performed by the entire control system. When the term “controller” is used in the present disclosure, it may refer to a case of including a single controller, as wells as a case of including a plurality of controllers or a case of including a control system configured by a plurality of controllers.

The memory 121c is configured with, for example, a flash memory, a hard disk drive (HDD), a solid state drive (SSD), etc. A control program for controlling operations of the processing apparatus, a process recipe describing procedures and conditions for substrate processing (described later), etc. are readably recorded and stored in the memory 121c. The process recipe is a combination that causes the controller 121 to execute each procedure for the substrate processing (described later) in the processing apparatus to obtain a predetermined result. The process recipe functions as a program. Hereinafter, the process recipe, the control program, and the like are collectively and simply referred to as programs (program products). Further, the process recipe is also simply referred to as a recipe. In the present disclosure, the term “program” may refer to a case of solely including the recipe, a case of solely including the control program, or a case of including both. The RAM 121b is configured as a memory area (work area) where programs, data, and the like read by the CPU 121a are temporarily held.

The I/O port 121d is connected to the MFCs 241a to 241e, 541a and 541b, the valves 243a to 243e, 543a and 543b, the concentration sensor 547, the pressure sensors 245 and 545, the APC valves 244 and 544, the vacuum pumps 246 and 546, the temperature sensors 263 and 563, the heaters 207 and 507, the rotator 267, the boat elevator 115, the shutter opening/closing mechanism 115s, the wafer deliverer 125, the gate valve 602, the opener 604, etc.

The CPU 121a is configured to read and execute the control program from the memory 121c and is configured to be capable of reading the recipe from the memory 121c in response to an input of an operation command from the input/output device 122, etc. The CPU 121a is configured to be capable of, according to contents of the read recipe, controlling flow rate regulating operations for various substances (various gases) by the MFCs 241a to 241e, 541a and 541b, opening/closing operations of the valves 243a to 243e, 543a and 543b, pressure regulating operations by the APC valves 244 and 544 based on opening/closing operations of the APC valves 244 and 544 and the pressure sensors 245 and 545, start and stop of the vacuum pumps 246 and 546, temperature regulating operations of the heaters 207 and 507 based on the temperature sensors 263 and 563, operations of rotating the boat 217 with the rotator 267 and adjusting a rotation speed of the boat 217, a raising/lowering operation of the boat 217 by the boat elevator 115, an opening/closing operation of the shutter 219s by the shutter opening/closing mechanism 115s, a transfer operation by the wafer deliverer 125, an opening/closing operation by the gate valve 602, an opening/closing operation by the opener 604, and the like.

The controller 121 may be configured by installing, on the computer, the above-mentioned program recorded and stored in the external memory 123. The external memory 123 includes, for example, a magnetic disk such as a HDD, an optical disk such as a CD, a semiconductor memory such as a USB memory or a SSD, and the like. The memory 121c or the external memory 123 is configured as a computer-readable recording medium. Hereinafter, the memory 121c and the external memory 123 may be collectively referred to as a recording medium. When the term “recording medium” is used in the present disclosure, it may refer to a case of solely including the memory 121c, a case of solely including the external memory 123, or a case of including both. The program may be provided to the computer by using a communication means such as the Internet or a dedicated line, without using the external memory 123.

### (2) Processing Process

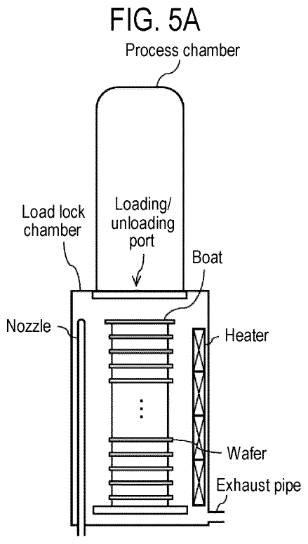

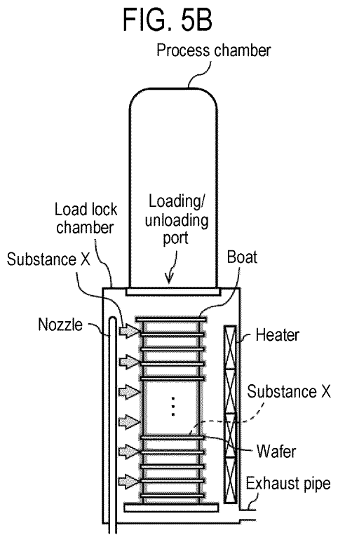

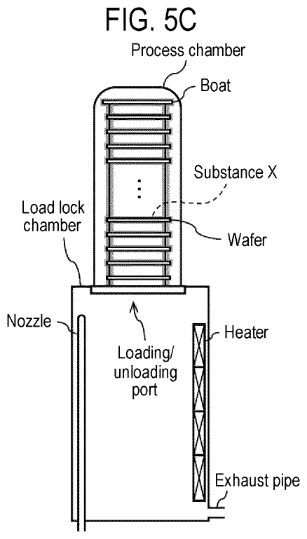

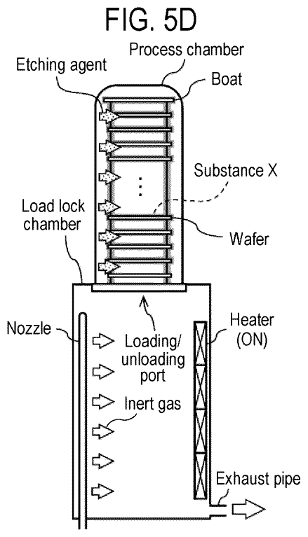

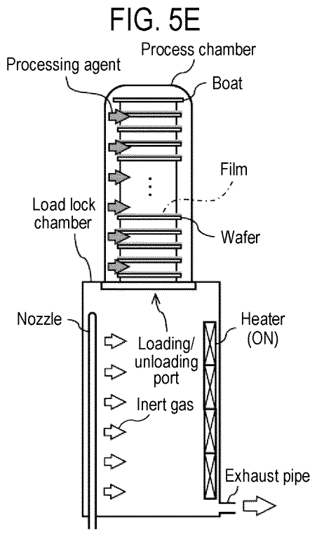

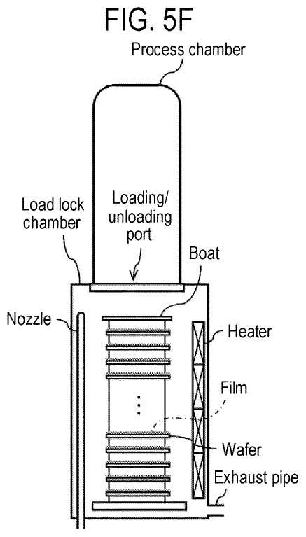

As one of processes (methods) of manufacturing a semiconductor device by using the processing apparatus described above, an example of a method of processing a substrate (processing method), i.e., a processing sequence of continuously performing a process of etching a surface of a wafer 200 as a substrate and a process of growing a film on the etched wafer 200 is described primarily with reference to FIGS. 3 and 5A to 5F. In the following description, operations of each part constituting the processing apparatus is controlled by the controller 121.

The processing sequence according to the embodiments includes:
(a) step A of supplying a substance X to a substrate (hereinafter referred to as a wafer 200) disposed in a second process chamber (hereinafter referred to as a load lock chamber 501), which is in fluid communication with a first process chamber (hereinafter referred to as a process chamber 201) via a loading/unloading port 204, so that the substance X is adsorbed on the wafer 200;
(b) step B of transferring the wafer 200 on which the substance X is adsorbed from the load lock chamber 501 into the process chamber 201; and
(c) step C of supplying an etching agent to the wafer 200 in the process chamber 201 so that the etching agent reacts with the substance X to etch a surface of the wafer 200.

In the following example, there is described a case where the processing sequence further includes:
step D of, after step C, transferring the wafer 200 from the process chamber 201 into the load lock chamber 501;
step E of, after step B and before step D, exhausting an inside of the load lock chamber to reduce a concentration of the substance X in the load lock chamber 501;
step F of increasing an internal temperature of the load lock chamber 501; and
step G of supplying an inert gas into the load lock chamber 501 to purge the load lock chamber 501.

Further, in the following example, there is described a case where the processing sequence includes: step H of, after step C and before step D, supplying a processing agent to the wafer 200, whose surface is etched, to process the wafer 200. Moreover, in the following example, there is described a case where, in step H, a film-forming agent is supplied as the processing agent to the wafer 200, whose surface is etched, to form a film on the wafer 200 with the etched surface.

The term “wafer” used in the present disclosure may refer to a wafer itself or a laminated body including a wafer and a predetermined layer or film formed on a surface of the wafer. The term “surface of a wafer” used in the present disclosure may refer to a surface of a wafer itself or a surface of a predetermined film or the like formed on a wafer. The expression “forming a predetermined film on a surface of a wafer” described in the present disclosure may mean forming a predetermined film directly on a surface of a wafer itself or forming a predetermined film on a film or the like formed on a wafer. The term “substrate” used in the present disclosure is synonymous with the term “wafer.”

The terms “agent” and “substance” used in the present disclosure include at least one selected from the group of a gaseous substance and a liquid substance. The liquid substance includes a mist-like substance. That is, each of the substance X, the etching agent, the processing agent, and the reducing agent may contain a gaseous substance, a liquid substance such as a mist-like substance, or both.

### Step A: Supplying Substance X to Substrate

First, when the transfer container 700 accommodating the processing target wafers 200 arrives at the mounting table 606, the opener 604 opens a lid of the transfer container 700 and the loading/unloading port 605, and the wafer deliverer 125 loads the wafers 200 from the transfer container 700 into the delivery chamber 601. Then, through the loading/unloading port 603 opened by opening the gate valve 602, the wafer deliverer 125 charges the wafers 200 from the delivery chamber 601 to the boat 217 in the load lock chamber 501 (wafer charging).

An oxide may be formed on the surface of the wafer 200. The oxide may include at least one selected from the group of a non-stoichiometric silicon oxide film (SiOₓ film, where x is a real number less than 2) and a stoichiometric silicon oxide film (SiO₂ film). The oxide may also include at least one selected from the group of a native oxide film and a chemical oxide film. The SiOₓ film and the SiO₂ film are hereinafter collectively referred to as SiO film.

After the wafer charging is completed, the gate valve 602 is closed to seal the loading/unloading port 603, and the boat 217 holding the wafers 200 is kept in a standby state in the load lock chamber 501, as shown in FIG. 5A. In this state, the inside of the load lock chamber 501 is kept airtight. In addition, the furnace opening of the process chamber 201, i.e., the loading/unloading port 204, is closed (sealed) by the shutter 219s.

Thereafter, as needed, the load lock chamber 501 is exhausted (depressurized) by the vacuum pump 546 to a desired pressure (vacuum level). At this time, the internal pressure of the load lock chamber 501 is measured by the pressure sensor 545, and the APC valve 544 is feedback-controlled based on this measured pressure information. Further, as needed, the load lock chamber 501 is heated by the heater 507 to a desired processing temperature. At this time, the state of supplying electric power to the heater 507 is feedback-controlled based on the temperature information detected by the temperature sensor 563 so that the load lock chamber 501 achieves a desired temperature distribution.

Next, the substance X is supplied to the wafers 200 disposed in the load lock chamber 501. In this step, the substance X is supplied while the wafers 200 are held on the boat 217 and transferred into the load lock chamber 501. In this step, the substance X is supplied to the wafers 200 while the loading/unloading port 204 is closed.

Specifically, the valve 543a shown in FIG. 3 is opened to allow the gas containing the substance X to flow into the gas supply pipe 532a. The gas containing the substance X is regulated in its flow rate by the MFC 541a, supplied into the load lock chamber 501 via the nozzle 549, and exhausted from the exhaust port 531a. At this time, the substance X is supplied to the wafers 200 and the boat 217, and each of the wafers 200 and the boat 217 is exposed to the substance X (substance X supply and exposure). At this time, the valve 543b may be opened to supply an inert gas into the load lock chamber 501 via the nozzle 549.

By supplying the substance X to the wafers 200 and the boat 217 under the condition described below, it is possible to cause at least one selected from the group of the substance X and a portion of molecular structures constituting the substance X (hereinafter collectively referred to as substance X) to be adsorbed on surfaces of these components, as shown in FIG. 5B. The substance X may be adsorbed in a substantially uniform amount across the entire surfaces of the wafers 200 disposed in the load lock chamber 501 and across the entire arrangement direction of the wafers 200 disposed in the load lock chamber 501. As shown in FIG. 3, the nozzle 549 is installed on a lateral side of an arrangement region of the wafers 200 along the arrangement direction of the wafers 200, and a plurality of gas supply holes are formed on a side surface of the nozzle 549 so as to correspond to the respective wafers 200, which makes it possible to improve inter-substrate uniformity of an amount of substance X adsorbed. Further, by rotating the boat 217 and the wafers 200 using the rotator 267 or the like while supplying the substance X, it is possible to improve in-plane uniformity of an amount of substance X adsorbed.

Processing condition when supplying the substance X in step A is exemplified as follows.
Processing temperature: 10 to 60 degrees C, specifically 20 to 50 degrees C
Processing pressure: 100 to 800 Torr, specifically 700 to 800 Torr, more specifically 750 to 770 Torr (i.e., approximately atmospheric pressure)
Processing time: 0.1 to 120 minutes, specifically 1 to 60 minutes
Substance X-containing gas supply flow rate: 0.01 to 20 slm, specifically 0.01 to 10 slm
Inert gas supply flow rate (per gas supply pipe): 0 to 20 slm, specifically 0 to 10 slm
   At this time, in the load lock chamber 501, a ratio of a vapor pressure of the substance X to a saturated vapor pressure (e.g., a relative humidity if the substance X is water (H₂O)) is, for example, more than 20%, desirably 65% or more.

In the present disclosure, when a numerical range such as “10 to 60 degrees C” is expressed, both the lower and upper limits are included in the range. For example, “10 to 60 degrees C” means “10 degrees C or higher and 60 degrees C or lower.” The same applies to other numerical ranges. In the present disclosure, the term “processing temperature” refers to a temperature of a space where processing is performed (the temperature inside the load lock chamber 501 in step A, and the temperature inside the process chamber 201 in steps C and H). In the present disclosure, the term “processing pressure” refers to a pressure in a space where the processing is performed (the pressure inside the load lock chamber 501 in step A, and the pressure inside the process chamber 201 in steps C and H). In addition, the term “processing time” refers to a time during which the processing continues. Further, when a supply flow rate includes 0 slm, 0 slm means that the substance (gas) is not supplied. These terms also apply to the following description.

The substance X adsorbed on the wafers 200 and the boat 217 reacts with the etching agent supplied into the process chamber 201 in step C, which is described later, to generate predetermined reaction products (etching species), thereby promoting an etching reaction on the surfaces of the wafers 200. In other words, the substance X adsorbed on the wafers 200 and the boat 217 functions as a reaction accelerator that promotes progress of the etching reaction performed in step C.

Therefore, by regulating at least one selected from the group of an amount of the gas containing the substance X and a concentration of the gas containing the substance X supplied to the wafers 200 and the boat 217 in step A, it is possible to increase or decrease an amount of the substance X adsorbed on the wafers 200 and the boat 217, and to control an amount of etching on the surfaces of the wafers 200 in step C, which is described later.

For example, by increasing the supply flow rate (or concentration of the substance X contained in the gas) of the gas containing the substance X supplied to the wafers 200 and the boat 217 in step A, the amount of the substance X adsorbed on the wafers 200 and the boat 217 is increased, making it possible to increase the amount of etching on the surfaces of the wafers 200 in step C, which is described later. Further, by decreasing the supply flow rate (or concentration of the substance X contained in the gas) of the gas containing the substance X supplied to the wafers 200 and the boat 217 in step A, the amount of the substance X adsorbed on the wafers 200 and the boat 217 is decreased, making it possible to decrease the amount of etching on the surfaces of the wafers 200 in step C, which is described later. The concentration of the substance X supplied may also be controlled by regulating a flow rate of the inert gas supplied from the nozzle 549.

Further, by regulating the internal temperature of the load lock chamber 501 in step A, it is possible to increase or decrease the amount of the substance X adsorbed on the wafers 200 and the boat 217, thereby controlling the amount of etching on the surfaces of the wafers 200 in step C, which is described later.

For example, in step A, by increasing the internal temperature of the load lock chamber 501, it is possible to increase a maximum amount of a gaseous substance X that can exist per unit volume inside the load lock chamber 501 (equivalent to a saturated water vapor amount if the substance X is water). This makes it possible to increase the amount of the substance X adsorbed on the wafers 200 and the boat 217 in step A, thereby increasing the amount of etching on the surfaces of the wafers 200 in step C, which is described later. In order to allow the wafers 200 to adsorb an amount of the substance X that substantially accelerates the etching reaction, the temperature in step A is desirably, for example, 10 degrees C or higher, more desirably 20 degrees C or higher. However, if the temperature is too high, a temperature of the wafer 200 increases, making it easier for the substance X adsorbed on the wafer 200 to desorb. Therefore, the temperature in step A is desirably 60 degrees C or lower, more desirably 50 degrees C or lower. Further, for example, by decreasing the internal temperature of the load lock chamber 501 in step A, it is possible to reduce the amount of the substance X adsorbed on the wafers 200 and the boat 217, thereby reducing the amount of etching on the surfaces of the wafers 200 in step C, which is described later.

In addition, by regulating a supply time of the substance X supplied to the wafers 200 in step A, it is possible to increase or decrease the amount of the substance X adsorbed on the wafers 200 and the boat 217, thereby controlling the amount of etching on the surfaces of the wafers 200 in step C, which is described later.

For example, by lengthening the supply time of the substance X supplied to the wafers 200 in step A, it is possible to increase the amount of the substance X adsorbed on the wafers 200 and the boat 217 in step A, and to increase the amount of etching on the surfaces of the wafers 200 in step C, which is described later. Further, by shortening the supply time of the substance X supplied to the wafers 200 in step A, it is possible to decrease the amount of the substance X adsorbed on the wafers 200 and the boat 217 in step A, and to decrease the amount of etching on the surfaces of the wafers 200 in step C, which is described later.

The amount of the substance X adsorbed on the wafers 200 and the boat 217 in step A is desirably set to an amount such that most of the substance X is consumed by performing step C, which is described later. This makes it possible to avoid influence of the substance X on substrate processing in step H, which is performed after step C. When the amount of the substance X adsorbed on the wafers 200 and the boat 217 in step A is excessive or when the amount of the substance X consumed in step C is insufficient, a portion of the adsorbed substance X may be removed, for example, after step A and before step B, from the surfaces of the wafers 200 and the boat 217 by, for example, increasing the internal temperature of the load lock chamber 501. Alternatively, for example, after step C and before step H, the remaining substance X may be entirely removed from the surfaces of the wafers 200 and the boat 217 by, for example, increasing the internal temperature of the process chamber 201.

As the substance X, for example, a substance containing oxygen (O) and hydrogen (H), such as water (H₂O) or hydrogen peroxide (H₂O₂), may be used.

The inert gas may be a nitrogen (N) gas, or a rare gas such as an argon (Ar) gas, a helium (He) gas, a neon (Ne) gas, a xenon (Xe) gas or the like. One or more of these gases may be used as the inert gas. This also applies to the steps described below.

### Step B: Transferring Substrate Into First Process Chamber

After step A and/or during a period leading up to the completion of step A, an interior of the process chamber 201 is heated by the heater 207 to a desired processing temperature. In step B, the internal temperature of the process chamber 201 is desirably set to be higher than the internal temperature of the load lock chamber 501.

When the interior of the process chamber 201 reaches a desired processing temperature, the wafers 200 on which the substance X is adsorbed are transferred into the process chamber 201 while being held by the boat 217 on which the substance X is adsorbed.

Specifically, the shutter 219s is moved by the shutter opening/closing mechanism 115s to open the opening at the lower end of the manifold 209. Thereafter, as shown in FIG. 5C, the boat 217 supporting the wafers 200 is lifted by the boat elevator 115 and loaded into the process chamber 201. In this state, the seal cap 219 closes the lower end of the manifold 209, i.e., the loading/unloading port 204, via the O-ring 220b.

Thereafter, the process chamber 201 is vacuum-exhausted (depressurized) by the vacuum pump 246 to a desired pressure (vacuum level). Further, the rotator 267 starts to rotate the wafers 200. The heating and exhaust of the process chamber 201 and the rotation of the wafers 200 are continued at least until processing of the wafers 200 is completed.

### Step C: Etching

After step B is completed, an etching agent is supplied to the wafers 200, on which the substance X is adsorbed, in the process chamber 201.

Specifically, the valve 243a is opened to allow the etching agent to flow into the gas supply pipe 232a. The etching agent is regulated in its flow rate by the MFC 241a, supplied into the process chamber 201 via the nozzle 249a, and exhausted from the exhaust port 231a. At this time, as shown in FIG. 5D, the etching agent is supplied to the wafers 200 from a lateral side of the wafers 200, thus exposing the wafers 200 to the etching agent. At this time, the valves 243d and 243e may be opened to supply an inert gas into the process chamber 201 via the nozzles 249a and 249b, respectively.

By supplying the etching agent to the wafers 200 under the processing condition to be described later, the etching agent reacts with the substance X or a portion of the molecular structures of the substance X that is adsorbed in advance on the wafers 200 and the boat 217, thereby making it possible to etch the surfaces of the wafers 200.

For example, when the oxide on the surfaces of the wafers 200 includes a silicon oxide (SiO₂), the substance X pre-adsorbed on the wafers 200 and the boat 217 includes water (H₂O), and the etching agent supplied into the process chamber 201 includes hydrogen fluoride (HF) as a F-containing substance, it is possible to perform the reactions shown in the following formulae under the condition described below. That is, in step C, it is possible to etch and remove the oxide (SiO₂) present on the surfaces of the wafers 200 by the etching species (HF₂⁻, etc.) produced by the reaction between the substance X (H₂O) and the etching agent (HF).

2HF+H₂O→HF₂⁻+H₃O⁺

SiO₂+2HF₂⁻+2H₃O⁺→SiF₄+4H₂O

As described above, according to the present disclosure, it is possible to initiate the etching of the oxide (SiO₂) on the surfaces of the wafers 200 by using, as a trigger, the reaction between the etching agent (HF) supplied into the process chamber 201 and a trace amount of the substance X (H₂O) or a portion of its molecular structure (HₓO) that is adsorbed in advance on the wafers 200 and the boat 217.

When the etching of the oxide begins, trace amounts of the substance X (H₂O) and the like that are adsorbed in advance to the wafers 200 and the boat 217 are consumed. However, in the reaction system in step C, moisture (H₂O) is produced by the etching of the oxide. Therefore, in step C, it is possible to etch the oxide on the surfaces of the wafers 200 by repeating the above-described reaction in a chain reaction without additionally supplying the substance X into the process chamber 201. If the substance X is additionally supplied into the process chamber 201 in step C, an amount of the substance X in the reaction system becomes excessive, which may hinder the progress of the etching reaction.

As described above, in step A, the substance X may be adsorbed in a substantially uniform amount over the entire surfaces of the wafers 200 disposed in the load lock chamber 501 and over the entire arrangement direction of the wafers 200 disposed in the load lock chamber 501. In this case, in step C, promoting effect of the substance X on the etching reaction may be obtained uniformly over the entire surfaces of the wafers 200 in the process chamber 201 and over the entire arrangement direction of the wafers 200.

After etching the surfaces of the wafers 200, the valve 243a is closed to stop the supply of the etching agent into the process chamber 201. Then, the process chamber 201 is vacuum-exhausted to remove gaseous substances and the like remaining in the process chamber 201. At this time, the valves 243d and 243e are opened to supply an inert gas into the process chamber 201 via the nozzles 249a and 249b. The inert gas supplied from the nozzles 249a and 249b acts as a purge gas, thereby purging the process chamber 201.

Processing condition when supplying the etching agent in step C is exemplified as follows.
Processing temperature: room temperature (25 degrees C) to 170 degrees C, specifically 25 to 150 degrees C
Processing pressure: 10 to 4,000 Pa, specifically 500 to 2,000 Pa
Etching agent supply flow rate: 0.5 to 3 slm, specifically 1 to 2 slm
Etching agent supply time: 1 to 120 minutes, specifically 5 to 60 minutes
Inert gas supply flow rate (per gas supply pipe): 0 to 10 slm, specifically 1 to 5 slm

Herein, if the processing temperature when supplying the etching agent in step C is set to be lower than the room temperature (25 degrees C), an etching rate may be increased. However, if another process such as a film formation process or the like is performed at least either before or after the etching process, a time needed to change the processing temperature between the etching process and another process (temperature increasing time and/or temperature decreasing time) may become too long, which may result in a decrease in productivity.

By setting the processing temperature to be equal to or higher than the room temperature (25 degrees C), it is possible to maintain a high etching rate while shortening the time needed to change the processing temperature between the etching process and another process, thereby suppressing a decrease in productivity.

As described above, a F-containing substance may be used as the etching agent, and for example, a F- and hydrogen (H)-containing substance such as HF may be used as the etching agent. Further, for example, fluorine (F₂), nitrogen trifluoride (NF₃), chlorine trifluoride (ClF₃), chlorine fluoride (ClF), and the like may be used as the etching agent. One or more of these substances may be used as the etching agent.

### Step H: Substrate Processing

Thereafter, the wafers 200, whose surfaces are etched, are heated by the heater 207 to a desired processing temperature. After the wafers 200 reach the desired processing temperature, a precursor, which is a film-forming agent, is supplied to the wafers 200 as a processing agent. In this step, a reducing agent is also supplied to the wafers 200 along with the precursor.

Specifically, the valves 243b and 243c are opened to allow the precursor and the reducing agent to flow into the gas supply pipes 232b and 232c, respectively. The precursor and the reducing agent are regulated in their flow rates by the MFCs 241b and 241c, respectively, supplied into the process chamber 201 via the nozzle 249b, and exhausted from the exhaust port 231a. At this time, as shown in FIG. 5E, the precursor and the reducing agent as processing agents are supplied to the wafers 200 from the lateral side of the wafers 200, exposing the wafers 200 to the precursor and the reducing agent (precursor+reducing agent supply and exposure). At this time, the valves 243d and 243e may be opened to supply an inert gas into the process chamber 201 via the nozzles 249a and 249b, respectively.

By supplying the precursor and the reducing agent to the wafers 200 under the processing condition described below, it is possible to form a predetermined film on the surface of the etched wafer 200. For example, when the surface of the wafer 200 exposed by the etching process is made of monocrystalline Si and when the precursor and the reducing agent are made of substances described below, it is possible to grow and form an epitaxial Si film on the surface of the wafer 200.

After a predetermined film is formed on the surface of the wafer 200, the valves 243b and 243c are closed to stop the supply of the precursor and the reducing agent into the process chamber 201.

Processing condition when supplying the precursor and the reducing agent in step D is exemplified as follows.
Processing temperature: 500 to 650 degrees C, specifically 550 to 600 degrees C
Processing pressure: 4 to 200 Pa, specifically 1 to 120 Pa
Processing time: 10 to 120 minutes, specifically 20 to 60 minutes
Precursor supply flow rate: 0.1 to 5 slm, specifically 0.2 to 3 slm
Reducing agent supply flow rate: 1 to 20 slm, specifically 1 to 10 slm
Inert gas supply flow rate (per gas supply pipe): 0 to 20 slm, specifically 0.1 to 10 slm

The processing agent (precursor) may be, for example, a silicon hydride such as monosilane (SiH₄), disilane (Si₂H₆), trisilane (Si₃H₈), tetrasilane (Si₄H₁₀), or the like. One or more of these substances may be used as the precursor.

As the reducing agent, for example, H-containing substances such as hydrogen (H), deuterium (D), and the like, or deuterium (D)-containing substances may be used. One or more of these substances may be used as the reducing agent.

### Step D: Transfer to Second Process Chamber

After step H is completed, an inert gas is supplied as a purge gas into the process chamber 201 from each of the nozzles 249a and 249b and exhausted through the exhaust port 231a. Thus, the process chamber 201 is purged, and gases, reaction by-products, or the like remaining in the process chamber 201 are removed from the process chamber 201. The internal atmosphere of the process chamber 201 is then replaced with the inert gas, and the internal pressure of the process chamber 201 is returned to the atmospheric pressure.

Thereafter, the seal cap 219 is lowered by the boat elevator 115, thereby opening the lower end of the manifold 209. Then, as shown in FIG. 5F, the processed wafers 200 supported by the boat 217 are unloaded from the lower end of the manifold 209 to an outside of the reaction tube 203, i.e., into the load lock chamber 501 (boat unloading). After the boat unloading, the shutter 219s is moved, and the opening at the lower end of the manifold 209, i.e., the loading/unloading port 204, is closed by the shutter 219s. Further, after the boat unloading, the gate valve 602 is opened.

The processed wafers 200, held in the boat 217 that is unloaded into the load lock chamber 501, are discharged from the boat 217 by the wafer deliverer 125 through the loading/unloading port 603, and are then accommodated back into the transfer container 700 via the delivery chamber 601. The processed wafers 200 are transferred to the next process.

### Steps E, F, and G: Discharge of Substance X From Second Process Chamber

When step D is performed, the processed wafers 200 are exposed to an internal atmosphere of the load lock chamber 501. If the substance X supplied in step A remains within the load lock chamber 501, the surfaces of the wafers 200 processed in step H may be contaminated by the substance X and oxidized depending on a concentration of the substance X in the load lock chamber 501.

Therefore, it is desirable to perform step E of, during at least a portion of a period between step B and step D, operating the vacuum pump 546 to exhaust the load lock chamber 501 and reduce the concentration of the substance X in the load lock chamber 501.

Further, it is more desirable to perform step F of, during at least a portion of the period between step B and step D, increasing an output of the heater 507 to raise the internal temperature of the load lock chamber 501. By performing this step, it is possible to vaporize the liquid substance X remaining inside the load lock chamber 501, thus changing into an easily dischargeable state.

Further, it is more desirable to perform step G of, during at least a portion of the period between step B and step D, opening the valve 543b to supply an inert gas into the load lock chamber 501 via the nozzle 549 to purge the inside of the load lock chamber 501. By performing this step, it is possible to promote discharge of the substance X from the load lock chamber 501.

As a result, it is possible to reduce the concentration of the substance X in the load lock chamber 501 at the timing when step D is started. This makes it possible to prevent the surfaces of the wafers 200 processed in step H from being contaminated or oxidized by the substance X remaining in the load lock chamber 501 when step D is performed. To reliably obtain this effect, it is desirable not to start step D until the concentration of the substance X in the load lock chamber 501 is equal to or lower than a predetermined value. The concentration of the substance X in the load lock chamber 501 may be monitored using the concentration sensor 547 installed in the exhaust pipe 531.

Environmental condition within the load lock chamber 501 at the start of step D is exemplified as follows.
Processing temperature: 0 to 100 degrees C, specifically room temperature (25 degrees C) to 50 degrees C
Ratio of vapor pressure to saturated vapor pressure of substance X (relative humidity if substance X is water): 0 to 30%, specifically 0 to 5%

Also, if step F is performed, in order to enable step A to be performed promptly when the processed wafers 200 are removed from the load lock chamber 501 and then the wafers 200 to be processed next are loaded into the load lock chamber 501, it is desirable that step F′ of reducing the internal temperature of the load lock chamber 501, which was increased in step F, desirably to the internal temperature of the load lock chamber 501 needed in step A, is executed before step D is performed.

This completes the processing processes in the embodiments of the present disclosure.

As described above, steps C and H may be performed in the same process chamber (in-situ). By performing a series of processes in-situ, the wafers 200 are not exposed to the ambient air during the process, and stable processing may be performed consistently while the wafers 200 are kept under vacuum.

### (3) Effects of Embodiments

According to the embodiments, one or more of the following effects may be obtained.

(a) In step A, the substance X is adsorbed on the surface of the substrate. In step C, the etching agent is supplied to the substrate. As a result, when etching the surface of the substrate, the etching agent and the substance X are reacted with each other, and the reaction product (etching species) produced by this reaction accelerates the etching reaction, making it possible to efficiently etch the surface of the substrate.

In particular, since the etching reaction is accelerated, even when reactivity of the etching reaction decreases as the temperature of the substrate increases (e.g., even when a SiO₂ film is etched using a HF gas as the etching agent), it becomes possible to maintain the etching rate while increasing the temperature of the substrate in step C. By increasing the temperature of the substrate in step C, it becomes possible to shorten a time needed to heat the substrate in step H, thus improving the productivity.

In addition, in step A, the substance X is adsorbed over the entire surface of the substrate disposed in the second process chamber. Further, in step A, the substance X is adsorbed in a substantially uniform amount over the entire arrangement direction of the substrates disposed in the second process chamber. Thus, in step C, the aforementioned promoting effect on the etching reaction may be obtained uniformly over the entire surface of the substrate and between the plurality of substrates. As a result, it is possible to improve the uniformity, i.e., the in-plane uniformity and the inter-plane uniformity of the etching process.

Further, in step A, the substance X is adsorbed on the substrate in the second process chamber adjacent to the first process chamber, whereby in step B, it is possible to directly load the substrate on which the substance X is adsorbed from the second process chamber into the first process chamber without being exposed to the ambient air. As a result, in step C, it is possible to enhance quality of the etching process on the surface of the substrate. For example, it becomes possible to improve controllability and reproducibility of the amount of etching on the surface of the substrate and in-plane distribution of the amount of etching.

Further, in step C, disposing a non-product substrate or the like to which the substance X is attached is not needed in the first process chamber. Thus, it is possible to increase the number of substrates that is processed at one time in the first process chamber, thereby improving the productivity.

(b) After performing step B and before starting step D, step E is performed to reduce the concentration of the substance X in the second process chamber. This makes it possible to avoid exposure of the substance X to the substrate in the second process chamber when starting step D. As a result, it is possible to keep clean the surface of the substrate on which step H is performed and to prevent oxidation of the film formed on the substrate in step H.

(c) After performing step B and before starting step D, step F is performed to raise the internal temperature of the second process chamber. This makes it possible to efficiently reduce the concentration of the substance X in the second process chamber before starting step D, thereby effectively obtaining the above-mentioned effects.

(d) After performing step B and before starting step D, step G is performed to purge the internal atmosphere of the second process chamber with an inert gas. This makes it possible to efficiently reduce the concentration of the substance X in the second process chamber before starting step D, thereby effectively obtaining the above-mentioned effects.

(e) After performing step C and before starting step D, step H is performed to supply the processing agent to the substrate whose surface is etched and cleaned, thereby processing the substrate. This makes it possible to process the substrate efficiently. Further, if step H is a film formation process for forming a film on the surface of the substrate, it is possible to reduce an impurity concentration (oxygen concentration, etc.) at an interface between the substrate and the film.

(f) In step A, the substance X is supplied to the substrate in a state in which the loading/unloading port 204 is closed. Thus, when performing step A, it is possible to prevent the substance X from entering the first process chamber when performing step A. Then, when performing step C, the concentration (partial pressure) of the substance X in the first process chamber can be appropriately controlled. As a result, it becomes possible to improve the controllability and reproducibility of the amount of etching on the surface of the substrate, the in-plane distribution of the amount of etching, and the like.

(g) In step B, the internal temperature of the first process chamber is set to be higher than the internal temperature of the second process chamber. This makes it possible to maintain the temperature of the substrate in the first process chamber lower than the internal temperature of the second process chamber in step B, thereby suppressing desorption of the substance X adsorbed on the substrate from the substrate. Further, in the subsequent step C, by raising the temperature of the substrate in the first process chamber, which is preheated to a temperature higher than the temperature in the second process chamber, it becomes possible to efficiently proceed with the etching process performed in the first process chamber.

(h) Step D is not started until the concentration of the substance X in the second process chamber becomes equal to or lower than a predetermined value. This makes it possible to more reliably prevent contamination of the processed substrate with the substance X when starting step D.

(i) In step A, the substance X is adsorbed on each of the substrate and the substrate holder, and in step B, the substrate and the substrate holder are transferred into the first process chamber. As a result, in step C, it is possible to use the substance X adsorbed on the substrate as well as the substance X adsorbed on the substrate holder in the etching process, thereby increasing efficiency of etching on the surface of the substrate.

(j) By regulating at least one selected from the group of the flow rate of the gas containing the substance X, supply time of the gas containing the substance X, and concentration (partial pressure) of the substance X contained in the gas supplied to the substrate and the internal pressure of the second process chamber in step A, it is possible to regulate the amount of the substance X adsorbed on the substrate and control the amount of etching on the surface of the substrate in step C. For example, by setting the internal pressure of the second process chamber to approximately atmospheric pressure (750 to 770 Torr) in step A, the concentration (partial pressure) of the substance X in the second process chamber is increased, which makes it possible to allow the substance X to be efficiently adsorbed on the substrate.

(k) By regulating the internal temperature of the second process chamber in step A, it becomes possible to control the amount of etching on the surface of the substrate in step C.

(l) By regulating the supply time of the substance X supplied to the substrate in step A, the amount of the substance X adsorbed on the substrate is regulated, which makes it possible to control the amount of etching on the surface of the substrate in step C.

(m) In step C, it is possible to efficiently etch the surface of the substrate by the etching species produced by the reaction between the substance X and the etching agent.

(n) When the substance X contains an O- and H-containing substance such as H₂O, H₂O₂, or the like, it is possible to effectively obtain the above-mentioned effects. In addition, when the etching agent contains an F-containing substance, it is possible to effectively obtain the above-mentioned effects.

(o) It is possible to similarly obtain the above-mentioned effects even when a predetermined substance is arbitrarily selected and used from the above-mentioned various substances X, various etching agents, various processing agents (precursors and reducing agents), and various inert gases.

### (4) Modifications

The processing sequence and processing apparatus configuration in the embodiments may be modified as shown in the following modifications. These modifications may be combined as desired. Unless otherwise specified, the processing procedure and processing condition for each step in each modification may be the same as the processing procedure and processing condition for each step in the processing sequence described above.

### Modification 1

When performing step C, a shortage of the substance X may occur in some regions of the first process chamber. In this case, in step A, an amount of the substance X adsorbed on the substrate corresponding to the region of the shortage of the substance X among the plurality of substrates may be made greater (higher) than an amount of the substance X adsorbed on the other substrates. Also, in this case, in step A, an amount of the substance X adsorbed on a portion of the substrate holder corresponding to the region of the shortage of the substance X may be made greater (higher) than an amount of the substance X adsorbed on the other portions. That is, in step A, at least one selected from the group of a flow rate, supply time, and concentration of the substance X supplied to some substrates may be different from that supplied to the other substrates. Further, in step A, at least one selected from the group of a flow rate of the gas containing the substance X, supply time of the gas containing the substance X, and concentration of the substance X contained in the gas supplied to one portion of the substrate holder may be different from that supplied to the other portions.

For example, a plurality of nozzles each corresponding to upper, middle, and lower portions of the second process chamber may be used to ensure that at least one selected from the group of a flow rate of the gas containing the substance X, supply time of the gas containing the substance X, and concentration of the substance X contained in the gas supplied from each nozzle may be made different from one another in step A. This makes it possible to vary the amount of the substance X adsorbed on the substrate or the substrate holder as described above.

Further, for example, zone heaters corresponding to the upper, middle, and lower portions of the second process chamber may be used to ensure that heating conditions for the upper, middle, and lower heaters are made different from one another in step A. This makes it possible to vary the amount of the substance X adsorbed on the substrate or the substrate holder as described above.

In this modification as well, the same effects as those of the above-described embodiments may be obtained.

Further, according to this embodiment, in step A, it is possible to vary the amount of the substance X adsorbed on the substrate or the substrate holder depending on positions within the first process chamber and consequently, in step C, it is possible to regulate the etching amount of the surface of the substrate depending on the positions within the first process chamber. As a result, it is possible to suppress, for example, the etching amount of the surface of the substrate from varying according to the positions within the first process chamber, i.e., between the substrates.

### Modification 2

In step A, the internal temperature of the second process chamber may be set to be higher than the internal temperature of the first process chamber.

In this modification as well, the same effects as those of the above-described embodiments may be obtained.

Further, according to this modification, it is possible to increase the maximum amount (saturated vapor pressure) of gaseous substance X that can exist per unit volume in the second process chamber and consequently, in step A, it is possible to allow the substance X to be efficiently adsorbed on the substrate and the substrate holder. As a result, it is possible to efficiently perform the etching process in step C.

### Modification 3

If the substance X is water, in step A, the substance X may be supplied to the second process chamber by introducing the ambient air. That is, water vapor in the ambient air may be used as the substance X. In this modification as well, the same effects as those of the above-described embodiments may be obtained.

### Modification 4

The concentration meter for the substance X is not limited to the case of being installed in the exhaust pipe that exhausts the second process chamber, but may be installed inside the second process chamber. In this modification as well, the same effects as those of the above-described embodiments may be obtained.

### Modification 5

The heating of the second process chamber performed in step F or the like is not limited to using the heater installed in the second process chamber; but may also be performed by supplying a heated inert gas or the like into the second process chamber. In this modification as well, the same effects as those of the above-described embodiments may be obtained.

### Modification 6

The surface of the substrate processed in the above-described embodiments may be formed to expose both an oxide and a nitride. That is, the substrate may include both an oxide surface and a nitride surface. Examples of the nitride include a silicon nitride film (SiN film), a silicon carbonitride film (SiCN film), a silicon oxycarbonitride film (SiOCN film), and the like. By performing the above-described etching process on a substrate with an oxide and a nitride formed on its surface, it is still possible to efficiently etch the oxide.

In this modification, by supplying the substance X to the substrate in the second process chamber in the manner described above, it is possible to adsorb the substance X on the oxide surface. Therefore, it is possible to increase an etching rate of the oxide in step C by the promoting effect of the substance X, adsorbed on the oxide surface, on the etching reaction of the oxide. On the other hand, in this modification, the substance X may also be adsorbed on the nitride surface in the second process chamber. However, the promoting effect of the substance X on the etching reaction as described above does not occur for the nitride. Therefore, in this modification, even when the substance X is adsorbed on both the oxide surface and the nitride surface, it is possible for the adsorbed substance X to selectively (i.e., preferentially) promote the etching reaction of the oxide.

For example, when the oxide is SiO₂, the nitride is Si₃N₄, the substance X is H₂O, and the etching agent is HF, as described above, the etching reaction of the oxide is generated by the etching species (HF₂⁻, etc.) produced by the reaction between the etching agent and the substance X, and therefore, it is possible to accelerate the etching reaction by adsorbing the substance X on the oxide surface. On the other hand, the etching reaction of the nitride is not substantially generated by the etching species produced by the reaction between the etching agent and the substance X, and therefore, even if the substance X is adsorbed on the nitride surface, the etching reaction is not accelerated. Therefore, in step C, the etching reaction of the oxide by the etching species proceeds selectively (i.e., preferentially) compared to the etching reaction of the nitride.

In a desired form of this modification, the internal pressure of the second process chamber may be set to, for example, approximately atmospheric pressure (750 to 770 Torr) in step A. By performing step A under such condition, it is possible to increase the concentration (partial pressure) of the substance X in the second process chamber, allowing the substance X to adsorbed on the oxide surface of the substrate at a sufficient density (amount of adsorption per unit area) and more selectively promoting the etching reaction for the oxide.

### Other Embodiments of the Present Disclosure

The embodiments of the present disclosure are specifically described above. However, the present disclosure is not limited to the above-described embodiments and may be modified in various ways without departing from the spirit of the present disclosure.

For example, in step H, a substance containing a semiconductor element other than Si may be used to form a semiconductor element-containing film on the substrate. For example, a substance containing a metal element such as tungsten (W), molybdenum (Mo), aluminum (Al), titanium (Ti), zirconium (Zr), hafnium (Hf), tantalum (Ta), or the like may be used as a precursor to form a metal element-containing film on the substrate. In these cases as well, the same effects as those of the above-described embodiments may be obtained.

Further, for example, in step H, instead of forming a film on the substrate, the surface of the substrate may be modified to a predetermined surface, or the surface of the substrate may be etched. In these cases as well, the same effects as those of the above-described embodiments may be obtained.

In the above-described embodiments, the example in which a process is performed using the batch-type processing apparatus that processes a plurality of substrates at a time is described. The present disclosure is not limited to the above-described embodiments and may be applied, for example, to a process performed using a single-substrate-type processing apparatus that processes one or several substrates at a time. Further, in the above-described embodiments, the example in which a process is performed using the processing apparatus including the hot-wall-type process furnace is described. The present disclosure is not limited to the above-described embodiments and may be applied to a process performed using a processing apparatus including a cold-wall-type process furnace.

In the above-described embodiments, steps C and H are performed in the same process chamber of the same processing apparatus (in-situ). The present disclosure is not limited to the above-described embodiments, and steps C and H may be performed in different process chambers of different processing apparatuses (ex-situ), or may be performed in different process chambers of the same processing apparatus.

Even when using these processing apparatuses, each process may be performed using the same processing procedures and conditions as in the above-described embodiments and modifications, and the same effects as those of the above-described embodiments and modifications may be obtained. Further, when steps C and H are performed ex-situ, it is possible to avoid introducing a processing agent (such as a film-forming agent) into the process chamber where the etching process is performed, and it is also possible to avoid introducing an etching agent (such as an F-containing substance) into the process chamber where the film formation process is performed. Accordingly, it is possible to prevent cross-contamination of the respective process chambers, and it is possible to improve qualities of the etching process and the film formation process.

The above-described embodiments and modifications may be used in combination as appropriate. The processing procedures and processing conditions in such a case may be the same as those of the above-described embodiments and modifications, for example.

According to the present disclosure in some embodiments, it is possible to efficiently etch a surface of a substrate.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a substance X to the substrate disposed in a second process chamber, which is in fluid communication with a first process chamber via a loading/unloading port, so that the substance X is adsorbed on the substrate;
(b) transferring the substrate on which the substance X is adsorbed from the second process chamber into the first process chamber; and
(c) supplying an etching agent to the substrate in the first process chamber so that the etching agent reacts with the substance X to etch a surface of the substrate.

2. The method of claim 1, further comprising:
(d) after (c), transferring the substrate from the first process chamber into the second process chamber; and
(e) after (b) and before (d), exhausting an inside of the second process chamber to reduce a concentration of the substance X in the second process chamber.

3. The method of claim 2, further comprising:
(f) after (b) and before (d), increasing an internal temperature of the second process chamber.

4. The method of claim 2, further comprising:
(g) after (b) and before (d), supplying an inert gas into the second process chamber to purge the second process chamber.

5. The method of claim 2, further comprising:
(h) after (c) and before (d), supplying a processing agent to the substrate, whose surface is etched, to process the substrate.

6. The method of claim 1, wherein in (a), the substance X is supplied to the substrate in a state in which the loading/unloading port is closed.

7. The method of claim 1, wherein in (b), an internal temperature of the first process chamber is set to be higher than an internal temperature of the second process chamber.

8. The method of claim 2, wherein (d) is not started until the concentration of the substance X in the second process chamber becomes equal to or less than a predetermined value.

9. The method of claim 1, wherein in (a), the substance X is supplied in a state in which the substrate is held by a substrate holder and transferred into the second process chamber, and the substance X is adsorbed on both the substrate and the substrate holder, and
wherein in (b), the substrate on which the substance X is adsorbed is transferred into the first process chamber in a state in which the substrate is held by the substrate holder on which the substance X is adsorbed.

10. The method of claim 1, wherein in (a), at least one selected from the group of an amount of a gas containing the substance X supplied to the substrate and a concentration of the substance X contained in the gas supplied to the substrate is regulated to control an amount of etching on the surface of the substrate in (c).

11. The method of claim 1, wherein in (a), an internal temperature of the second process chamber is regulated to control an amount of etching on the surface of the substrate in (c).

12. The method of claim 1, wherein in (a), a supply time of the substance X supplied to the substrate is regulated to control an amount of etching on the surface of the substrate in (c).

13. The method of claim 1, wherein in (c), the surface of the substrate is etched by etching species produced by a reaction between the substance X and the etching agent.

14. The method of claim 1, wherein the substance X includes an oxygen- and hydrogen-containing substance.

15. The method of claim 1, wherein the substance X includes at least one selected from the group of H₂O and H₂O₂.

16. The method of claim 1, wherein the etching agent includes a fluorine-containing substance.

17. The method of claim 1, wherein the substrate includes an oxide surface and a nitride surface, and
wherein in (c), the oxide surface is selectively etched relative to the nitride surface by etching species produced by a reaction between the substance X and the etching agent.

18. A method of manufacturing a semiconductor device, comprising the method of claim 1.

19. A non-transitory computer-readable recording medium storing a program that causes, by a computer, a substrate processing apparatus to perform:
(a) supplying a substance X to a substrate disposed in a second process chamber, which is in fluid communication with a first process chamber via a loading/unloading port, so that the substance X is adsorbed on the substrate;
(b) transferring the substrate on which the substance X is adsorbed from the second process chamber into the first process chamber; and
(c) supplying an etching agent to the substrate in the first process chamber so that the etching agent reacts with the substance X to etch a surface of the substrate.

20. A substrate processing apparatus, comprising:
a first process chamber in which an etching process for a substrate is performed;
a second process chamber in fluid communication with the first process chamber via a loading/unloading port;
a substance X supply system configured to supply a substance X to the substrate in the second process chamber;
an etching agent supply system configured to supply an etching agent to the substrate in the first process chamber;
a transferrer configured to transfer the substrate between the first process chamber and the second process chamber via the loading/unloading port; and
a controller configured to control the substance X supply system, the etching agent supply system, and the transferrer so as to perform:
(a) supplying the substance X to the substrate disposed in the second process chamber so that the substance X is adsorbed on the substrate;
(b) transferring the substrate on which the substance X is adsorbed from the second process chamber into the first process chamber; and
(c) supplying the etching agent to the substrate in the first process chamber so that the etching agent reacts with the substance X to etch a surface of the substrate.
